(19) United States
(12) Patent Application Publication
(10) Pub. No.: US 2012/0236502 A1
(43) Pub. Date: Sep. 20, 2012

(54) SHEET-SHAPED STRUCTURE, METHOD FOR MANUFACTURING SHEET-SHAPED STRUCTURE, ELECTRONIC DEVICE, AND METHOD FOR MANUFACTURING ELECTRONIC DEVICE

(75) Inventors: Yoshitaka Yamaguchi, Kawasaki (JP); Taisuke Iwai, Kawasaki (JP); Masaaki Norimatsu, Kawasaki (JP); Shinichi Hirose, Kawasaki (JP); Yohei Yagishita, Kawasaki (JP); Yukie Sakita, Kawasaki (JP)

(73) Assignee: FUJITSU LIMITED, Kawasaki-shi (JP)

(21) Appl. No.: 13/403,156

(22) Filed: Feb. 23, 2012

(30) Foreign Application Priority Data
Mar. 18, 2011 (JP) 2011-061623

(51) Int. Cl. H05K 7/20; B23P 11/00; B05D 5/12; B32B 5/16

(52) U.S. Cl. 361/704; 428/292.1; 29/428; 427/124

(57) ABSTRACT

According to an aspect of the embodiments, a sheet-shaped structure includes a bundle structure that includes a plurality of line-shaped structures of carbon atoms, a covering layer that covers the line-shaped structures in longitudinal directions of the line-shaped structures, respectively, and a filling layer that is disposed between the line-shaped structures covered with the covering layer.

### CROSS-REFERENCE TO RELATED APPLICATION

This application is based upon and claims the benefit of priority of the prior Japanese Patent Application No. 2011-061623, filed on Mar. 18, 2011, the entire contents of which are incorporated herein by reference.

### FIELD

The embodiments discussed herein are related to a sheet-shaped structure, a method for manufacturing the sheet-shaped structure, an electronic device, and a method for manufacturing the electronic device.

### BACKGROUND

With finer processing of semiconductor elements so as to improve the performance of electronic components for use in central processing units (CPUs) of servers and personal computers, the amount of heat generated per unit area is increasing. Thus, heat dissipation of electronic components is an urgent problem. Thus, a heat spreader made of a material having high thermal conductivity, such as copper, is mounted on a semiconductor element with a thermal interface material interposed therebetween.

It is desirable that a thermal interface material have high thermal conductivity and be in wide contact with fine asperities on the surfaces of a heat source and a heat spreader.

Under such situations, heat-conductive sheets made of line-shaped structures of carbon atoms, such as a carbon nanotube, have received attention as thermal interface materials. Carbon nanotube has very high thermal conductivity (1500 W/m·K) and also high flexibility and heat resistance and has high potential as a heat-dissipation material.

Japanese Laid-open Patent Publication No. 2010-118609 discloses a heat-conductive sheet including carbon nanotubes in which a thermoplastic resin filling layer is disposed between a plurality of line-shaped structures of carbon atoms, such as carbon nanotubes.

FIG. 1A and FIG. 1B illustrate a method for manufacturing an electronic device, which includes a carbon nanotube sheet as a heat-conductive sheet. The carbon nanotube sheet includes a thermoplastic resin filling layer.

As illustrated in FIG. 1A, a carbon nanotube sheet 103 including a thermoplastic resin filling layer is disposed on a semiconductor element 102 (heat generator) mounted on a circuit board 101. The semiconductor element 102 including the carbon nanotube sheet 103 thereon is then covered with a heat spreader 104 (heat dissipator). In the carbon nanotube sheet 103, bundles of carbon nanotubes 106 are closely packed and form a bundle structure 108.

As illustrated in FIG. 1B, the carbon nanotube sheet 103 is reflowed by heat treatment while the heat spreader 104 is under a load. This treatment melts a thermoplastic resin of a filling layer 105 in the carbon nanotube sheet 103. The thermoplastic resin is removed from the regions between the carbon nanotubes 106, the semiconductor element 102, and the heat spreader 104. Thus, the ends of each of the carbon nanotubes 106 in the carbon nanotube sheet 103 are coupled to the semiconductor element 102 and the heat spreader 104. Because of their flexibility, the carbon nanotubes 106 can be bend to follow the asperities on the surfaces of the semiconductor element 102 and the heat spreader 104.

Such a structure can increase the number of carbon nanotubes 106 coupled to the semiconductor element 102 and the heat spreader 104 and thicken the heat conduction path composed of a plurality of carbon nanotubes 106 between the semiconductor element 102 and the heat spreader 104. This can significantly reduce thermal resistance between the semiconductor element 102 and the heat spreader 104.

Subsequent cooling to room temperature solidifies the thermoplastic resin of the filling layer 105. Because of the adhesion properties of the thermoplastic resin, the semiconductor element 102 and the heat spreader 104 are fixed to the carbon nanotube sheet 103.

Examples of heat-conductive sheets including carbon nanotubes can be found in Japanese Laid-open Patent Publication No. 2010-118609 and Japanese Laid-open Patent Publication No. 2009-260238.

However, in a reflow process of the carbon nanotube sheet 103 described above, a deviation of load applied to the heat spreader 104 from a predetermined target value may result in an increase in thermal resistance between the semiconductor element 102 and the heat spreader 104.

FIGS. 2A and 2B are schematic views illustrating the carbon nanotube sheet 103 under a load in the reflow process of the carbon nanotube sheet 103.

As illustrated in FIG. 2A, in the reflow process of the carbon nanotube sheet 103, a load applied to the heat spreader 104 lower than the target value results in the presence of residual thermoplastic resin between the carbon nanotubes 106, the semiconductor element 102, and the heat spreader 104. The presence of residual thermoplastic resin reduces the number of carbon nanotubes 106 coupled to the semiconductor element 102 and the heat spreader 104 and narrows the heat conduction path composed of the carbon nanotubes 106 between the semiconductor element 102 and the heat spreader 104.

The carbon nanotubes 106 are flexible but have insufficient mechanical strength. Thus, the carbon nanotube sheet 103 has insufficient load tolerance. As illustrated in FIG. 2B, therefore, in the reflow process of the carbon nanotube sheet 103, a much higher load applied to the heat spreader 104 than the target value flattens the bundle structure 108 of the carbon nanotubes 106 in the carbon nanotube sheet 103. Because of this deformation, the carbon nanotubes 106 in the bundle structure 108 cannot follow the asperities on the surfaces of the heat generator and the heat dissipator. This reduces the number of carbon nanotubes 106 coupled to the semiconductor element 102 and the heat spreader 104 and narrows the heat conduction path composed of the carbon nanotubes 106 between the semiconductor element 102 and the heat spreader 104.

Thus, in the reflow process of the carbon nanotube sheet 103, whether the load applied to the heat spreader 104 is insufficient or excessively high, thermal resistance between the semiconductor element 102 and the heat spreader 104 increases.

Thus, in the reflow process of the carbon nanotube sheet 103, it is difficult to control the load applied to the heat spreader 104 and increase the yield in the manufacture of electronic devices.

### SUMMARY

According to an aspect of the embodiments, a sheet-shaped structure includes a bundle structure that includes a plurality of line-shaped structures of carbon atoms, a covering layer that covers the line-shaped structures in longitudinal directions of the line-shaped structures, respectively, and a filling layer that is dispose between the line-shaped structures covered with the covering layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are schematic views illustrating a method for manufacturing an electronic device, which includes a carbon nanotube sheet as a heat-conductive sheet;

FIGS. 2A and 2B are schematic views illustrating a carbon nanotube sheet under a load in a reflow process of the carbon nanotube sheet;

FIGS. 3A and 3B are schematic views illustrating the structure of a carbon nanotube sheet according to a first embodiment;

FIG. 4 is a schematic view of the entanglement of a plurality of carbon nanotubes in the carbon nanotube sheet;

FIGS. 5A to 5C are schematic cross-sectional views (part 1) illustrating a method for manufacturing the carbon nanotube sheet according to the first embodiment;

FIGS. 6A and 6B are schematic cross-sectional views (part 2) illustrating a method for manufacturing the carbon nanotube sheet according to the first embodiment;

FIGS. 7A and 7B are schematic cross-sectional views (part 3) illustrating a method for manufacturing the carbon nanotube sheet according to the first embodiment;

FIG. 8A is a graph illustrating the thickness retention of the carbon nanotube sheet as a function of the thickness of an aluminum oxide covering layer while the carbon nanotube sheet is under a certain load;

FIG. 8B is a graph illustrating the thermal resistance of the carbon nanotube sheet as a function of the thickness of the aluminum oxide covering layer while the carbon nanotube sheet is under a certain load;

FIG. 9 is a graph illustrating the thermal resistance and the thickness retention of the carbon nanotube sheet as a function of load when the aluminum oxide covering layer has a thickness of 20 nm;

FIG. 10 is a schematic view of the structure of an electronic device according to a fifth embodiment;

FIGS. 11A and 11B are schematic cross-sectional views (part 1) illustrating a method for manufacturing the electronic device 1000 according to the fifth embodiment; and

FIGS. 12A and 12B are schematic cross-sectional views (part 2) illustrating a method for manufacturing the electronic device 1000 according to the fifth embodiment.

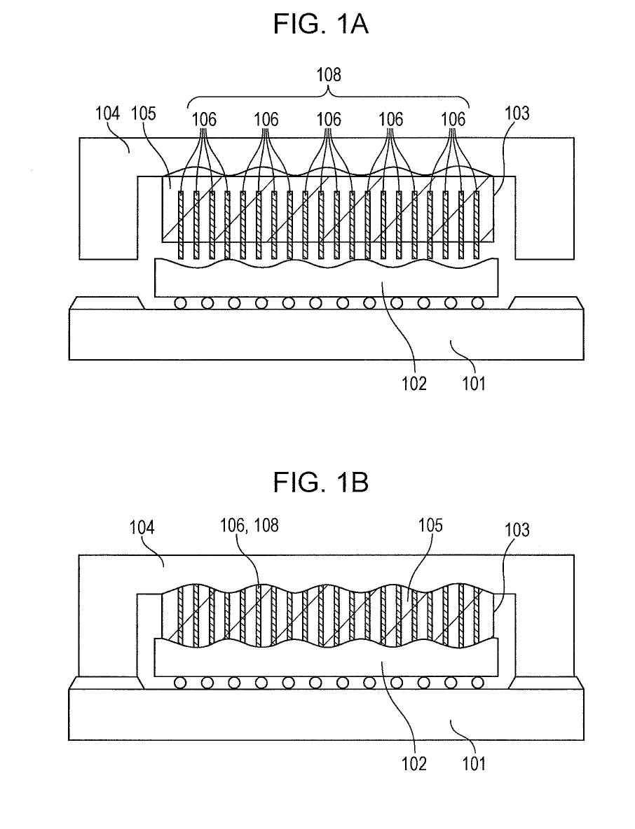

### DESCRIPTION OF EMBODIMENTS

The embodiments will be described below.

### 1. First Embodiment

1-1. Structure of Carbon Nanotube Sheet 300

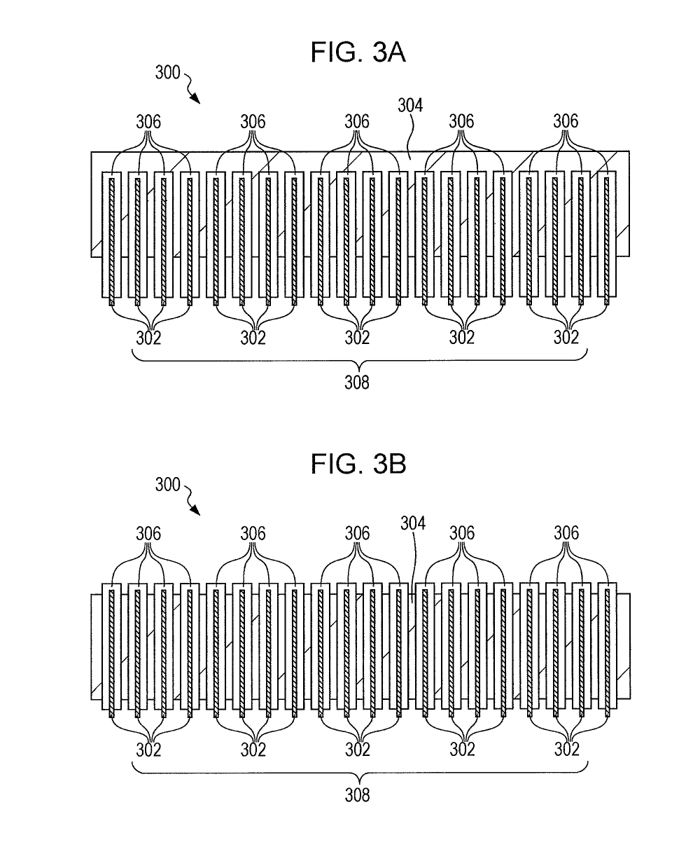

FIGS. 3A and 3B illustrate a sheet-shaped structure including a line-shaped structure of carbon atoms according to a first embodiment. FIGS. 3A and 3B illustrate a carbon nanotube sheet 300 including carbon nanotubes 302 as an example of a sheet-shaped structure including a line-shaped structure of carbon atoms. FIG. 3A illustrates a first sample of a carbon nanotube sheet according to the first embodiment. FIG. 3B illustrates a second sample of a carbon nanotube sheet according to the first embodiment. The carbon nanotube sheet 300 is a heat-conductive sheet used as a thermal interface material between a heat generator (for example, a semiconductor element) and a heat dissipator (for example, a heat spreader).

As illustrated in FIGS. 3A and 3B, the carbon nanotube sheet 300 includes a plurality of carbon nanotubes 302 disposed at intervals. The carbon nanotubes 302 are line-shaped structures of carbon atoms. The carbon nanotubes 302 may be monolayer carbon nanotubes or multilayer carbon nanotubes.

In the carbon nanotube sheet 300, the carbon nanotubes 302 are oriented in the thickness direction of the sheet, that is, in a direction across the surfaces of the sheet. The carbon nanotubes 302 may have any surface density and desirably have a surface density of 1×10¹⁰/cm² or more in terms of heat dissipation and electroconductivity. The carbon nanotubes 302 are closely packed as bundles and form a bundle structure 308. The carbon nanotubes 302 may have any diameter (mean value), for example, 25 μm.

The length of the carbon nanotubes 302 depends on the application of the carbon nanotube sheet 300 and is preferably, but is not limited to, in the range of approximately 5 to 500 μm. In the case that the carbon nanotube sheet 300 is used as a thermal interface material between a heat generator (for example, a semiconductor element) and a heat dissipator (for example, a heat spreader), it is desirable that the carbon nanotubes 302 have a sufficient length so as to fill the asperities of the surfaces of the heat generator and the heat dissipator.

As illustrated in FIGS. 3A and 3B, each of the carbon nanotubes 302 is covered with a covering layer 306 in the longitudinal direction. It is desirable that the covering layer 306 be formed so as to cover each of the carbon nanotubes 302 from one end to the other end.

The covering layer 306 can increase the mechanical strength of each of the carbon nanotubes 302 and consequently increase the mechanical strength of the bundle structure 308 of the carbon nanotubes 302. Thus, it is desirable that the covering layer 306 continuously cover the entire surface of each of the carbon nanotubes 302 from one end to the other end. The covering layer 306 may partly cover the surface of each of the carbon nanotubes 302 provided that the covering layer 306 can increase the mechanical strength of each of the carbon nanotubes 302.

The covering layer 306 may be a thin film on each of the carbon nanotubes 302 or aggregates of fine particles for covering each of the carbon nanotubes 302. The covering layer 306 may have any shape provided that the covering layer 306 can increase the mechanical strength of each of the carbon nanotubes 302.

Thus, in the carbon nanotube sheet 300, the covering layer 306 covering each of the carbon nanotubes 302 can increase the mechanical strength of the corresponding carbon nanotube 302. This can increase the mechanical strength of the bundle structure 308 of the carbon nanotubes 302 and consequently improve the load tolerance of the carbon nanotube sheet 300. In the case that the carbon nanotube sheet 300 is used as a thermal interface material between a heat generator (for example, a semiconductor element) and a heat dissipator (for example, a heat spreader), therefore, even the application of an excessive load in a reflow process rarely flattens the bundle structure 308 of the carbon nanotubes 302 in the carbon nanotube sheet 300. The carbon nanotubes 302 in the bundle structure 308 can be bent to follow the asperities on the surfaces of the heat generator and the heat dissipator.

The ends of each of the carbon nanotubes 302 may be covered with the covering layer 306. Although only one end of each of the carbon nanotubes 302 is covered with the covering layer 306 in FIGS. 3A and 3B, both ends of each of the carbon nanotubes 302 may be covered with the covering layer 306.

When the carbon nanotube sheet 300 that includes the carbon nanotubes 302 each having an end covered with the covering layer 306 is used as a thermal interface material between a heat generator and a heat dissipator, the covering layer 306 on the end of each of the carbon nanotubes 302 is disposed between the heat generator or the heat dissipator and the corresponding carbon nanotube 302.

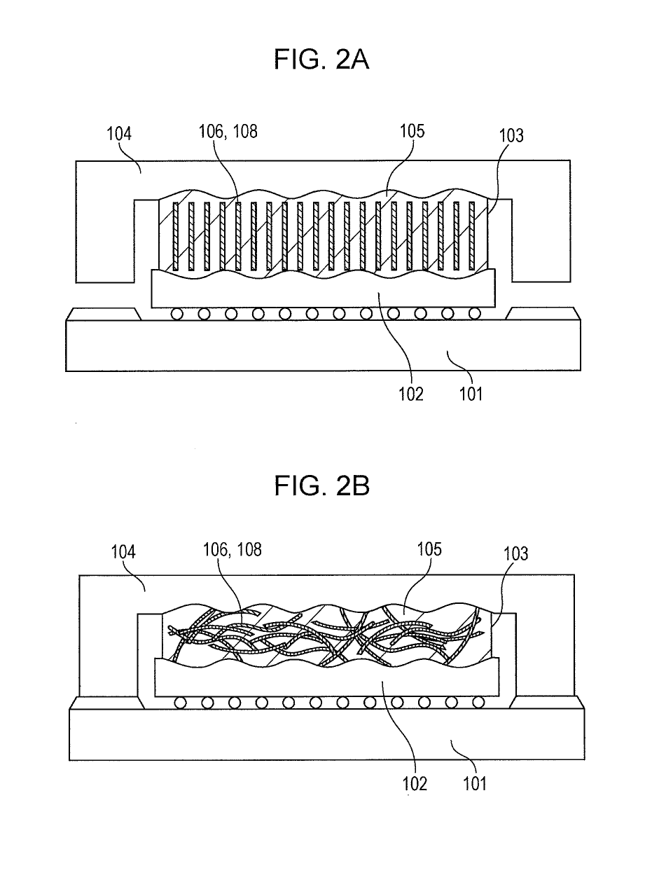

Thus, the covering layer 306 is desirably made of a material having a thermal conductivity higher than the thermal conductivity of a thermoplastic resin described below (approximately 0.1 W/m·K), although the covering layer 306 may be made of any material. When the thermal conductivity of the covering layer 306 is lower than the thermal conductivity of the thermoplastic resin, the thermal resistance between a heat generator and a heat dissipator may be higher in this case than in the case that the thermoplastic resin remains between the carbon nanotube and the heat generator and between the carbon nanotube and the heat dissipator, as illustrated in FIG. 2A.

It is desirable that the material of the covering layer 306 have a thermal conductivity higher than the thermal conductivity per unit area of the bundle structure 308 of the carbon nanotubes 302. This is because even the presence of the covering layer 306 between a heat generator or a heat dissipator and the corresponding carbon nanotube 302 does not impair the high thermal conductivity of the carbon nanotube 302. This is also because the covering layer 306 of each of the carbon nanotubes 302 can form an additional heat conduction path between the heat generator and the heat dissipator. The thermal conductivity per unit area of the bundle structure 308 of the carbon nanotubes 302 is approximately 47.1 W/m·K when the thermal conductivity per carbon nanotube is 1500 W/m·K, the carbon nanotubes have a diameter of 20 nm, and the carbon nanotubes have a surface density of 1×10¹⁰/cm².

The material of the covering layer 306 may be, but is not limited to, a metal oxide, such as aluminum oxide (Al₂O₃) or zinc oxide (ZnO), or a metal, such as copper (Cu), ruthenium (Ru), or platinum (Pt). Specific examples of the material of the covering layer 306 will be described in the following embodiments.

It is desirable that the covering layer 306 have a thickness (mean value) of 100 nm or less. An excessively large thickness of the covering layer 306 may result in reduced flexibility of the carbon nanotubes 302, make it difficult for the carbon nanotubes 302 to follow the asperities on the surfaces of a heat generator and a heat dissipator, and result in a reduced number of carbon nanotubes 302 directly coupled to the heat generator and the heat dissipator without the filling layer 304 being therebetween. Since the inherent mechanical strength of the bundle structure 308 of the carbon nanotubes 302 depends on the surface density of the carbon nanotubes 302, the permissible thickness of the covering layer 306 also depends on the surface density of the carbon nanotubes 302. However, since the surface density of the carbon nanotubes 302 has a lower limit in terms of heat dissipation and electroconductivity, the permissible thickness of the covering layer 306 also has an upper limit as described above.

The carbon nanotubes 302 each covered with the covering layer 306 are supported by the filling layer 304 disposed between the carbon nanotubes 302. The material of the filling layer 304 may be, but is not limited to, a thermoplastic resin.

The filling layer 304 may be made of any thermoplastic resin provided that the thermoplastic resin reversibly changes between liquid and solid in response to its temperature, is solid at room temperature and liquid at high temperature, and returns to solid by cooling while providing adhesion. The thermoplastic resin of the filling layer 304 may be appropriately selected on the basis of the melting temperature of the thermoplastic resin for the intended use of the carbon nanotube sheet 300.

The thermoplastic resin may be a hot-melt resin described below. The hot-melt resin may be a polyamide hot-melt resin, such as “Micromelt 6239” (softening point: 140° C.) manufactured by Henkel Japan Ltd., a polyester hot-melt resin, such as “DH598B” (softening point: 133° C.) manufactured by Nogawa Chemical Co., Ltd., a polyurethane hot-melt resin, such as “DH722B” manufactured by Nogawa Chemical Co., Ltd., a polyolefin hot-melt resin, such as “EP-90” (softening point: 148° C.) manufactured by Matsumura Oil Co., Ltd., an ethylene copolymer hot-melt resin, such as “DA574B” (softening point: 105° C.) manufactured by Nogawa Chemical Co., Ltd., an SBR hot-melt resin, such as “M-6250” (softening point: 125° C.) manufactured by Yokohama Rubber Co., Ltd., an EVA hot-melt resin, such as “3747” (softening point: 104° C.) manufactured by Sumitomo 3M Ltd., or a butyl rubber hot-melt resin, such as “M-6158” manufactured by Yokohama Rubber Co., Ltd.

As described above, in the carbon nanotube sheet 300, the covering layer 306 covering each of the carbon nanotubes 302 can increase the mechanical strength of the corresponding carbon nanotube 302. This can increase the mechanical strength of the bundle structure 308 of the carbon nanotubes 302 and consequently improve the load tolerance of the carbon nanotube sheet 300. Thus, even the application of an excessive load rarely flattens the bundle structure 308 of the carbon nanotubes 302 in the carbon nanotube sheet 300.

In the carbon nanotube sheet 300, therefore, many of the carbon nanotubes 302 are coupled to a heat generator and a heat dissipator without the filling layer 304 being therebetween, and the number of such carbon nanotubes can be increased. This can thicken the heat conduction path composed of the carbon nanotubes 302 between the heat generator and the heat dissipator. Thus, the carbon nanotube sheet 300 can reduce thermal resistance between the heat generator and the heat dissipator.

Furthermore, the carbon nanotube sheet 300 used as a thermal interface material between a heat generator (for example, a semiconductor element) and a heat dissipator (for example, a heat spreader) can improve the load tolerance of the carbon nanotube sheet 300. This can increase the margin for the load applied to the carbon nanotube sheet 300 and thereby facilitate load control in the reflow process.

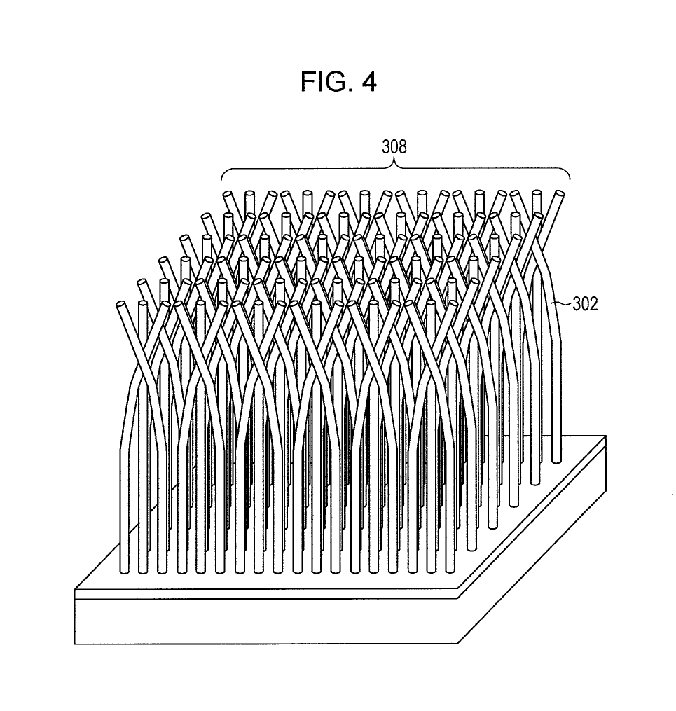

Although the description was omitted for the sake of simplicity in FIGS. 3A and 3B, the bundle structure 308 of the carbon nanotubes 302 actually includes carbon nanotubes entangled with each other, as illustrated in FIG. 4. Thus, in the bundle structure 308 of the carbon nanotubes 302, adjacent carbon nanotubes of the carbon nanotubes 302 actually support each other.

In the bundle structure 308 including such entangled carbon nanotubes, each of the carbon nanotubes 302 is covered with the covering layer 306. The carbon nanotubes 302 each reinforced by the covering layer 306 are entangled and support each other. Thus, an increase in the mechanical strength of each of the carbon nanotubes 302 is directly associated with an increase in the mechanical strength of the bundle structure 308 of the carbon nanotubes 302.

The covering layer 306 formed on each of entangled carbon nanotubes may combine adjacent carbon nanotubes of the carbon nanotubes 302. Thus, the carbon nanotubes 302 each reinforced by the covering layer 306 are combined. This also contributes to an increase in the mechanical strength of each of the carbon nanotubes 302 directly associated with an increase in the mechanical strength of the bundle structure 308 of the carbon nanotubes 302.

As illustrated in FIGS. 3A and 3B, in the carbon nanotube sheet 300, at least one end of each of the carbon nanotubes 302 is exposed. In the carbon nanotube sheet 300 illustrated in FIG. 3A, one end of each of the carbon nanotubes 302 is exposed. In the carbon nanotube sheet 300 illustrated in FIG. 3B, both ends of each of the carbon nanotubes 302 are exposed.

This allows the carbon nanotubes 302 to be coupled to a heat dissipator or a heat generator without the filling layer 304 being therebetween when the carbon nanotube sheet 300 is in contact with the heat dissipator or the heat generator, thus markedly increasing the heat conduction efficiency of the carbon nanotube sheet 300. Because of their electrical conductivity, the carbon nanotubes 302 each having exposed ends can be used as wiring components passing through the sheet. Thus, the carbon nanotube sheet 300 according to the first embodiment can be used as a vertical type wiring sheet, as well as a heat-conductive sheet.

The ends of each of the carbon nanotubes 302 covered with the covering layer 306 may be further covered with a heat-conductive film. The material of the heat-conductive film may be, but is not limited to, a metal or an alloy, for example, copper (Cu), nickel (Ni), or gold (Au). The heat-conductive film does not necessarily have a monolayer structure and may be a multilayer structure including two or three or more layers, such as a titanium (Ti) and gold (Au) multilayer structure.

The heat-conductive film can increase the area of a portion of the carbon nanotube sheet 300 in contact with an adherend (a heat dissipator or a heat generator) as compared with the carbon nanotube sheet 300 without the heat-conductive film. This can reduce thermal contact resistance between the carbon nanotubes 302 and the adherend and further reduce the thermal resistance of the carbon nanotube sheet 300. When the carbon nanotube sheet 300 is used as a vertical type wiring sheet, the heat-conductive film can increase the electrical conductivity of the carbon nanotube sheet 300.

1-2. Method for Manufacturing Carbon Nanotube Sheet 300

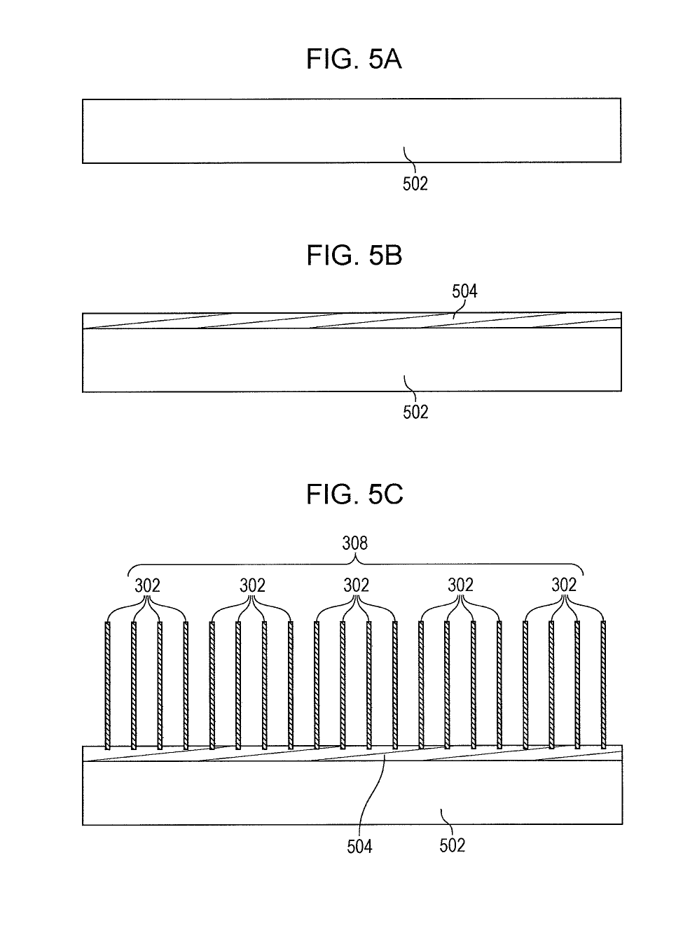

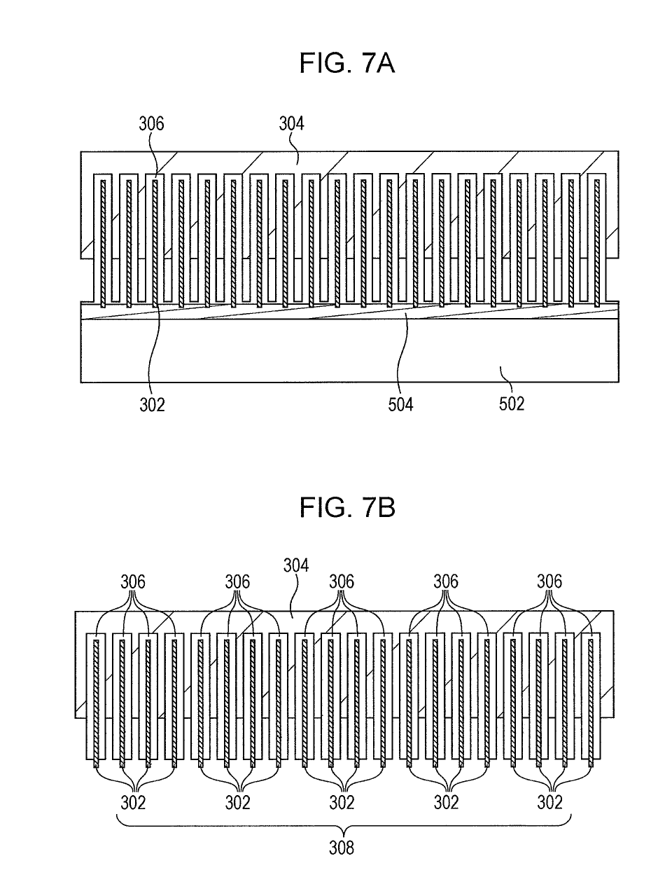

FIGS. 5A to 5C and FIGS. 7A and 7B are schematic cross-sectional views illustrating a method for manufacturing the carbon nanotube sheet 300 according to the first embodiment.

As illustrated in FIG. 5A, a substrate 502 on which the carbon nanotube sheet 300 is to be formed is prepared. The substrate 502 may be a semiconductor substrate, such as a silicon substrate, an insulating substrate, such as an alumina (sapphire) substrate, a MgO substrate, or a glass substrate, or a metal substrate. These substrates may include a thin film disposed thereon. For example, the substrate 502 may be a silicon substrate that includes a silicon oxide film having a thickness of approximately 300 nm disposed thereon.

The substrate 502 is removed after the growth of the carbon nanotubes 302. Thus, it is desirable that the substrate 502 does not deteriorate at the growth temperature of the carbon nanotubes 302. It is also desirable that at least a surface of the substrate 502 to be coupled to the carbon nanotubes 302 be formed of a material that allows the substrate 502 to be easily detached from the carbon nanotubes 302.

As illustrated in FIG. 5B, an iron (Fe) catalyst metal film 504, for example, having a thickness of 2.5 nm is then formed on the substrate 502, for example, by sputtering. The catalyst metal film 504 is not necessarily formed on the entire surface of the substrate 502. For example, the catalyst metal film 504 may be selectively formed on a predetermined region of the substrate 502 by a lift-off method.

The catalyst metal other than Fe may be cobalt (Co), nickel (Ni), gold (Au), silver (Ag), or platinum (Pt), or an alloy including at least one of these metals. The catalyst metal may also be metal fine particles having a controlled size manufactured with a differential mobility analyzer (DMA). The metal fine particles may be made of the same metal as the metal film.

The catalyst metal film 504 may have an underlying film, for example, made of molybdenum (Mo), titanium (Ti), hafnium (Hf), zirconium (Zr), niobium (Nb), vanadium (V), tantalum nitride (TaN), titanium silicide (TiSix), aluminum (Al), aluminum oxide (Al₂O₃), titanium oxide (TiOx), tantalum (Ta), tungsten (W), copper (Cu), gold (Au), platinum (Pt), palladium (Pd), or titanium nitride (TiN), or an alloy including at least one of these metals.

The carbon nanotubes 302 are then grown on the substrate 502, for example, by hot filament CVD, using the catalyst metal film 504 as a catalyst. The growth conditions of the carbon nanotubes 302 may include use of a gas mixture of acetylene and argon (partial pressure ratio 1:9) as a raw material gas, the total gas pressure of a deposition chamber of 1 kPa, the hot filament temperature of 1000° C., and the growth time of 25 minutes. The resulting multilayer carbon nanotube has a number of layers of approximately 5 in average, a mean diameter of 25 nm, and a length of 50 μm (growth rate: 2 μm/min).

The carbon nanotubes may also be formed by another film-forming method, such as thermal CVD or remote plasma CVD. The carbon nanotubes may be monolayer carbon nanotubes. The carbon raw material other than acetylene may be a hydrocarbon, such as methane or ethylene, or an alcohol, such as ethanol or methanol.

The length of the carbon nanotubes 302 depends on the application of the carbon nanotube sheet 300 and is preferably, but is not limited to, in the range of approximately 5 to 500 μn. In the case that the carbon nanotube sheet 300 is used as a thermal interface material between a heat generator (for example, a semiconductor element) and a heat dissipator (for example, a heat spreader), it is desirable that the carbon nanotubes 302 have a sufficient length so as to fill the asperities of the surfaces of the heat generator and the heat dissipator.

As illustrated in FIG. 5C, a bundle structure thus formed includes the carbon nanotubes 302 oriented in the direction normal to the surface of the substrate 502 (vertical orientation). Although not illustrated in FIG. 5C for the sake of simplicity, the bundle structure 308 of the carbon nanotubes 302 actually includes carbon nanotubes entangled with each other, as illustrated in FIG. 4.

The carbon nanotubes 302 formed under the growth conditions described above have a surface density of approximately 1×10¹¹/cm². This means that the carbon nanotubes 302 are formed on approximately 10% of the surface area of the substrate 502.

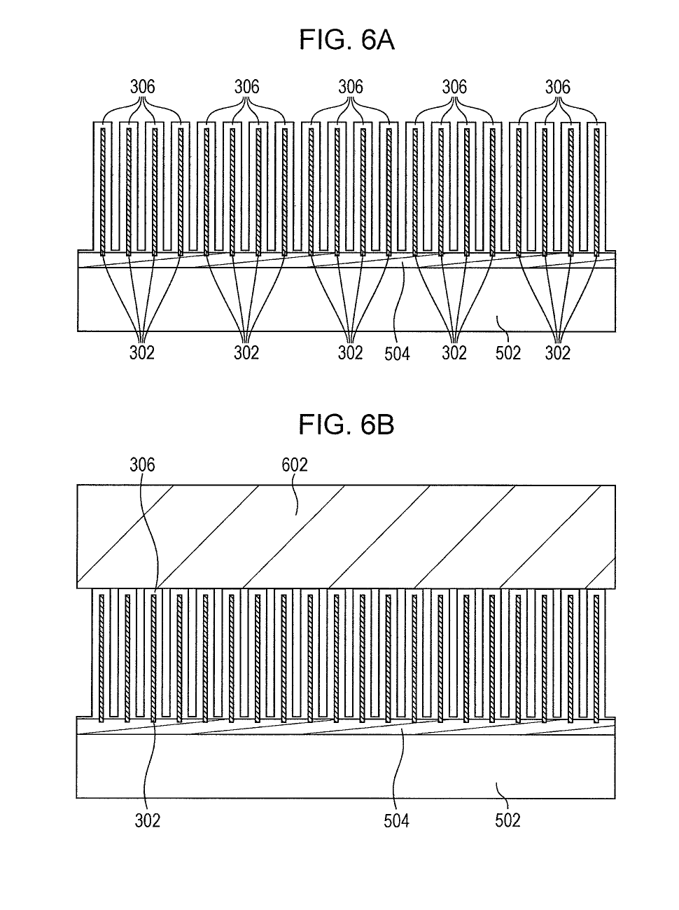

As illustrated in FIG. 6A, the covering layers 306 are formed by atomic layer deposition (ALD) on the entire surface of the substrate 502 on which the bundle structure 308 of the carbon nanotubes 302 is disposed. Each of the covering layers 306 covers the corresponding carbon nanotube 302 in the longitudinal direction. It is desirable that the covering layer 306 be formed so as to cover each of the carbon nanotubes 302 from one end to the other end. It is more desirable that the covering layer 306 continuously covers the entire surface of the corresponding carbon nanotube 302 from one end to the other end.

In order to cover each of the carbon nanotubes 302 in the longitudinal direction, the present inventors found that the covering layer 306 is preferably, but not limited to, be formed by ALD. In the bundle structure 308 of the carbon nanotubes 302, many carbon nanotubes 302 are closely packed in a small area. Thus, each region between the carbon nanotubes 302 forms a groove having a very high aspect ratio. The present inventors therefore found that a film-forming method with high surface coverage even for such a groove having a very high aspect ratio is desirable for the formation of the covering layer 306 so as to cover each of the carbon nanotubes 302 in the longitudinal direction. The present inventors noticed that ALD is a film-forming method with a high coverage even for a groove having a high aspect ratio and found that ALD is a suitable film-forming method.

Although one end of each of the carbon nanotubes 302 opposite the substrate 502 is covered with the corresponding covering layer 306, the other end on the side of the substrate 502 is not covered with the covering layer 306. The embodiment is not limited to this example.

The covering layer 306 may cover adjacent carbon nanotubes of the carbon nanotubes 302 as a continuous film. The covering layer 306 may also cover adjacent carbon nanotubes of the carbon nanotubes 302 as independent two or more films.

In the case of entangled carbon nanotubes as illustrated in FIG. 4, the covering layer 306 can cover adjacent carbon nanotubes of the carbon nanotubes 302 as a continuous film so as to combine the adjacent carbon nanotubes.

It is desirable that the covering layer 306 have a thickness (mean value) of 100 nm or less. The covering layer 306 may be a thin film on each of the carbon nanotubes 302 or aggregates of fine particles for covering each of the carbon nanotubes 302.

The covering layer 306 is desirably made of a material having a thermal conductivity higher than the thermal conductivity of a thermoplastic resin described below (approximately 0.1 W/m·K), although the covering layer 306 may be made of any material. It is desirable that the material of the covering layer 306 have a thermal conductivity higher than the thermal conductivity per unit area of the bundle structure 308 of the carbon nanotubes 302.

The material of the covering layer 306 may be, but is not limited to, a metal oxide, such as aluminum oxide (Al₂O₃) or zinc oxide (ZnO), or a metal, such as copper (Cu), ruthenium (Ru), or platinum (Pt). The film-forming conditions for the covering layer 306 depend on the material of the covering layer 306 and will be described below in EXAMPLES.

The covering layer 306 may be made of any material that can be deposited by ALD. Typical examples of the material that can be deposited by ALD include titanium oxide, hafnium oxide, iron oxide, indium oxide, lanthanum oxide, molybdenum oxide, niobium oxide, nickel oxide, ruthenium oxide, silicon oxide, vanadium oxide, tungsten oxide, yttrium oxide, zirconium oxide, manganese, iron, cobalt, nickel, copper, silver, and lanthanum.

As illustrated in FIG. 6B, a thermoplastic resin film 602 is placed on the carbon nanotubes 302 each covered with the covering layer 306. It is desirable that the thickness of the thermoplastic resin film 602 be appropriately determined in accordance with the length of the carbon nanotubes 302. For example, in order to form the carbon nanotube sheet 300 illustrated in FIG. 3A, the thickness of the thermoplastic resin film 602 is substantially the same as the length of the carbon nanotubes 302 and is suitably in the range of approximately 5 to 500 μm. In order to form the carbon nanotube sheet 300 illustrated in FIG. 3B, the thickness of the thermoplastic resin film 602 is slightly smaller than the length of the carbon nanotubes 302 and is suitably in the range of approximately 4 to 400 μm.

The thermoplastic resin of the thermoplastic resin film 602 may be a hot-melt resin. Examples of the hot-melt resin include polyamide hot-melt resin, polyester hot-melt resin, polyurethane hot-melt resin, polyolefin hot-melt resin, ethylene copolymer hot-melt resin, SBR hot-melt resin, EVA hot-melt resin, and butyl rubber hot-melt resin, as described above.

The present example employs a thermoplastic resin film 602 having a thickness of 100 μm made of a polyamide hot-melt resin “Micromelt 6239” manufactured by Henkel Japan Ltd. The hot-melt resin “Micromelt 6239” has a melting temperature in the range of 135° C. to 145° C. and a melt viscosity in the range of 5.5 to 8.5 Pa·s (225° C.).

The substrate 502 on which the thermoplastic resin film 602 is placed is then heated at a temperature of, for example, 195° C. The thermoplastic resin of the thermoplastic resin film 602 is melted and gradually flows into a groove between the carbon nanotubes 302 each covered with the covering layer 306. As illustrated in FIG. 7A, the thermoplastic resin of the thermoplastic resin film 602 flows into the groove to the extent that the thermoplastic resin does not reach the surface of the substrate 502.

The processing of the thermoplastic resin into a sheet in advance allows the amount of filling layer to be controlled in accordance with the thickness of the sheet. Thus, the heating temperature or the heating time can be controlled such that the filling layer does not reach the substrate 502.

The reason that the thermoplastic resin flow is stopped before reaching the substrate 502 is that this facilitates the removal of the carbon nanotube sheet 300 from the substrate 502. Thus, if the carbon nanotube sheet 300 can be easily removed from the substrate 502, the thermoplastic resin film 602 may reach the substrate 502.

The depth of the thermoplastic resin of the thermoplastic resin film 602 flowing into the groove between the carbon nanotubes 302 each covered with the covering layer 306 can be controlled by the heat-treatment time. In the case of the carbon nanotubes 302 having a length of 100 μm grown under the conditions described above, heat treatment at 195° C. for 1 minute allows the thermoplastic resin of the thermoplastic resin film 602 to flow into the groove to the extent that the thermoplastic resin does not reach the surface of the substrate 502.

It is desirable that the heating time of the thermoplastic resin film 602 that allows the thermoplastic resin of the thermoplastic resin film 602 to flow into the groove to the extent that the thermoplastic resin does not reach the surface of the substrate 502 is appropriately determined in accordance with the length of the carbon nanotubes 302, the melt viscosity of the thermoplastic resin, and the thickness of the thermoplastic resin film 602.

It is desirable that the thermoplastic resin be shaped into a film in advance. The thermoplastic resin also may be shaped into pellets or a rod.

After the thermoplastic resin film 602 has reached a predetermined depth, the thermoplastic resin film 602 is cooled to room temperature to be solidified. As illustrated in FIG. 7A, the thermoplastic resin of the thermoplastic resin film 602 forms the filling layer 304 that fills the grooves between the carbon nanotubes 302 each covered with the covering layer 306.

The carbon nanotubes 302 each covered with the covering layer 306 and the filling layer 304 are then removed from the substrate 502. Since the filling layer 304 (thermoplastic resin film 602) does not reach the substrate 502 as described above, the carbon nanotubes 302 each covered with the covering layer 306 are weakly coupled to the substrate 502. Thus, the carbon nanotubes 302 each covered with the covering layer 306 can be easily removed from the substrate 502.

After the carbon nanotubes 302 each covered with the covering layer 306 has been removed from the substrate 502, a portion of the covering layers 306 on the surface of the catalyst metal film 504 between the carbon nanotubes 302 remains on the catalyst metal film 504.

As illustrated in FIG. 7B, the carbon nanotube sheet 300 that includes the filling layer 304 between the carbon nanotubes 302 each covered with the covering layer 306 is completed.

### 2. Second Embodiment

2-1. Structure of Carbon Nanotube Sheet 300

In the second embodiment, aluminum oxide (Al₂O₃) is used as the material of the covering layer 306 of the carbon nanotube sheet 300 illustrated in FIG. 3A and FIG. 3B.

In the carbon nanotube sheet 300 according to the second embodiment, in the process illustrated in FIG. 6A, a covering layer 406 made of aluminum oxide is formed by ALD over the entire surface of the substrate 502 on which the bundle structure 308 of the carbon nanotubes 302 is formed. The film-forming conditions include the use of trimethylaluminum (Al(CH₃)₃) and water (H₂O) as raw material gases and the film-forming temperature of 200° C.

This method is a type of thermal ALD. Plasma enhanced ALD (PEALD) using plasma may also be used.

The aluminum oxide covering layer has a thickness of 20 nm.

Under these film-forming conditions, each of the carbon nanotubes 302 can be covered with the aluminum oxide covering layer 406 in the longitudinal direction of the carbon nanotubes 302. Under the film-forming conditions, the aluminum oxide covering layer 406 continuously covers the entire surface of each of the carbon nanotubes 302 from one end to the other end.

The aluminum oxide covering layer 406 covering each of the carbon nanotubes 302 can increase the mechanical strength of the corresponding carbon nanotube 302. This can increase the mechanical strength of the bundle structure 308 of the carbon nanotubes 302 and consequently improve the load tolerance of the carbon nanotube sheet 300.

In the case that the carbon nanotube sheet 300 is used as a thermal interface material between a heat generator (for example, a semiconductor element) and a heat dissipator (for example, a heat spreader), therefore, even the application of an excessive load in a reflow process rarely flattens the bundle structure 308 of the carbon nanotubes 302 in the carbon nanotube sheet 300.

The carbon nanotubes 302 in the bundle structure 308 can be bent to follow the asperities on the surfaces of the heat generator and the heat dissipator. Thus, many of the carbon nanotubes 302 are coupled to a heat generator and a heat dissipator without the filling layer 304 being therebetween, and the number of such carbon nanotubes can be increased. This can thicken the heat conduction path composed of the carbon nanotubes 302 between the heat generator and the heat dissipator. Thus, the carbon nanotube sheet 300 can reduce thermal resistance between the heat generator and the heat dissipator.

When the carbon nanotube sheet 300 that includes the carbon nanotubes 302 each having an end covered with the aluminum oxide covering layer 406 is used as a thermal interface material between a heat generator and a heat dissipator, the aluminum oxide covering layer 406 on the end of each of the carbon nanotubes 302 is disposed between the heat generator or the heat dissipator and the corresponding carbon nanotube 302.

Aluminum oxide has a thermal conductivity of approximately 30 W/m·K. The thermal conductivity of aluminum oxide is higher than the thermal conductivity of a thermoplastic resin (approximately 0.1 W/m·K) but is lower than the thermal conductivity per unit area of the bundle structure 308 of the carbon nanotubes 302 (approximately 47.1 W/m·K).

Thus, the aluminum oxide covering layer 406 on the end of each of the carbon nanotubes 302 may increase the thermal resistance between the heat generator and the heat dissipator. However, as described above, the heat conduction path composed of the carbon nanotubes 302 between the heat generator and the heat dissipator can be thicken in the carbon nanotube sheet 300 to reduce thermal resistance between the heat generator and the heat dissipator as a whole. The details are described below.

2-2. Experimental Example of Carbon Nanotube Sheet 300

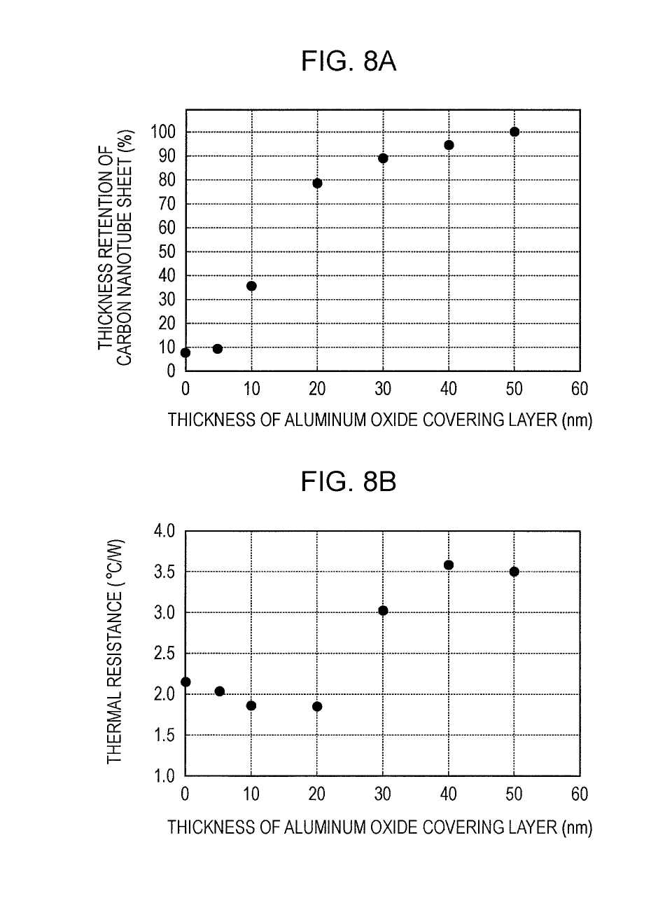

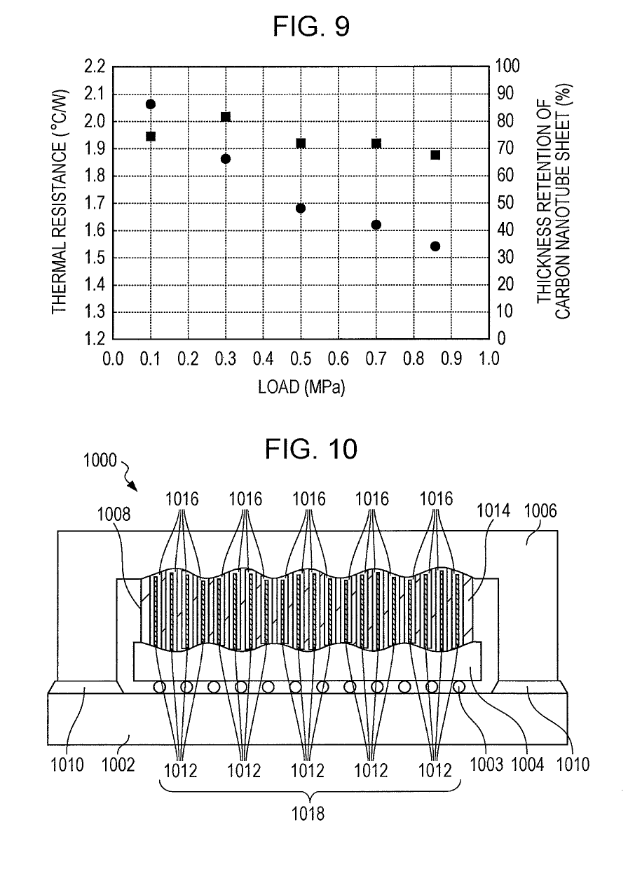

FIGS. 8A and 8B and FIG. 9 illustrate the experiment results for the carbon nanotube sheet 300 that includes the covering layer 306 made of aluminum oxide (Al₂O₃). The experiment on the carbon nanotube sheet 300 will be described below with reference to FIGS. 8A and 8B and FIG. 9.

FIG. 8A is a graph illustrating the thickness retention of the carbon nanotube sheet 300 as a function of the thickness of the aluminum oxide covering layer 406 while the carbon nanotube sheet 300 is under a certain load.

In the experimental example illustrated in FIG. 8A, the carbon nanotube sheet 300 was placed between a heat generator and a heat dissipator. After reflowing under a load of 0.5 MPa, the thickness retention of the carbon nanotube sheet 300 was measured. The thickness retention of the carbon nanotube sheet 300 is the ratio of the thickness of the carbon nanotube sheet 300 under the load to the thickness of the carbon nanotube sheet 300 under no load and ranges from 0% to 100%.

As illustrated in FIG. 8A, without the aluminum oxide covering layer 406 (thickness 0 nm), the thickness retention of the carbon nanotube sheet 300 is 10% or less. This indicates that the bundle structure 308 of the carbon nanotubes 302 is flattened.

With an increase in the thickness of the aluminum oxide covering layer 406, the thickness retention of the carbon nanotube sheet 300 increases monotonously. In particular, when the thickness of the carbon nanotube sheet 300 was increased from 10 nm to 20 nm, the thickness retention of the carbon nanotube sheet 300 increased significantly, resulting in a large variation in the thickness retention.

FIG. 8B is a graph illustrating the thermal resistance of the carbon nanotube sheet 300 as a function of the thickness of the aluminum oxide covering layer 406 while the carbon nanotube sheet 300 is under a certain load.

In the experimental example illustrated in FIG. 8B, the carbon nanotube sheet 300 was placed between a heat generator and a heat dissipator. After reflowing under a load of 0.5 MPa, the thermal resistance of the carbon nanotube sheet 300 was measured. The thermal resistance of the carbon nanotube sheet 300 refers to the thermal resistance between a heat generator (for example, a semiconductor element) and a heat dissipator (for example, a heat spreader) when the carbon nanotube sheet 300 is used as a thermal interface material between the heat generator and the heat dissipator.

As illustrated in FIG. 8B, with an increase in the thickness of the aluminum oxide covering layer 406 from 0 nm (no aluminum oxide covering layer 406), the thermal resistance of the carbon nanotube sheet 300 decreases gradually. The thermal resistance of the carbon nanotube sheet 300 is lowest when the thickness of the aluminum oxide covering layer 406 is 20 nm. With a further increase in the thickness of the aluminum oxide covering layer 406, the thermal resistance of the carbon nanotube sheet 300 increases.

The experimental results illustrated in FIGS. 8A and 8B indicate the following. When the thickness of the aluminum oxide covering layer 406 is 0 nm (no aluminum oxide covering layer 406), the carbon nanotubes 302 themselves have insufficient mechanical strength, and the bundle structure 308 of the carbon nanotubes 302 also has insufficient mechanical strength. Thus, under a load, the bundle structure 308 of the carbon nanotubes 302 is flattened.

Thus, the carbon nanotubes 302 in the bundle structure 308 may not follow the asperities on the surfaces of the heat generator and the heat dissipator. This reduces the number of carbon nanotubes coupled to the heat generator and the heat dissipator without the filling layer 304 being therebetween and narrows the heat conduction path composed of the carbon nanotubes 302 between the heat generator and the heat dissipator. Thus, the carbon nanotube sheet 300 has high thermal resistance.

In contrast, with an increase in the thickness of the aluminum oxide covering layer 406, the carbon nanotubes 302 themselves have increased mechanical strength, and consequently the bundle structure 308 of the carbon nanotubes 302 also has increased mechanical strength. This improves the load tolerance of the carbon nanotube sheet 300. Thus, the application of a load rarely flattens the bundle structure 308 of the carbon nanotubes 302. Thus, the carbon nanotubes 302 in the bundle structure 308 can be bent to follow the asperities on the surfaces of the heat generator and the heat dissipator.

This increases the number of carbon nanotubes coupled to the heat generator and the heat dissipator without the filling layer 304 being therebetween and thickens the heat conduction path composed of the carbon nanotubes 302 between the heat generator and the heat dissipator. Thus, the carbon nanotube sheet 300 has low thermal resistance.

With an excessive increase in the thickness of the aluminum oxide covering layer 406, the carbon nanotubes 302 themselves have increased mechanical strength, and consequently the bundle structure 308 of the carbon nanotubes 302 also has increased mechanical strength. This improves the load tolerance of the carbon nanotube sheet 300.

However, the carbon nanotubes 302 themselves have excessively high mechanical strength, and the aluminum oxide covering layer 406 impairs the inherent flexibility of the carbon nanotubes 302. Thus, the carbon nanotubes 302 in the bundle structure 308 may not be bent to follow the asperities on the surfaces of the heat generator and the heat dissipator.

Furthermore, the thickness of the aluminum oxide covering layer 406 on an end of each of the carbon nanotubes 302 is increased. This increases the thickness of the aluminum oxide covering layer 406 between the heat generator or the heat dissipator and each of the carbon nanotubes 302 and increases thermal resistance between the heat generator and the heat dissipator. This is because the thermal conductivity of aluminum oxide (approximately 30 W/m·K) is lower than the thermal conductivity per unit area of the bundle structure 308 of the carbon nanotubes 302 (approximately 47.1 W/m·K), as described above.

Thus, an excessive increase in the thickness of the aluminum oxide covering layer 406 results in increased thermal resistance of the carbon nanotube sheet 300.

These results indicate that the thickness of the aluminum oxide covering layer 406 has an upper limit because of a trade-off between the improvement in the mechanical strength of the carbon nanotubes 302 and a decrease in the flexibility of the carbon nanotubes 302, as well as the thermal resistance of the aluminum oxide covering layer 406 itself. The upper limit may be 100 nm, as described in the first embodiment. In the carbon nanotube sheet 300, the thickness of the aluminum oxide covering layer 406 is suitably approximately 20 nm.

FIG. 9 is a graph illustrating the thermal resistance and the thickness retention of the carbon nanotube sheet 300 as a function of load when the aluminum oxide covering layer 406 has a thickness of 20 nm. In FIG. 9, filled circles represent the thermal resistance of the carbon nanotube sheet 300, and filled squares represent the thickness retention of the carbon nanotube sheet 300.

In the experimental example illustrated in FIG. 9, the carbon nanotube sheet 300 that includes the aluminum oxide covering layer 406 having a thickness of 20 nm was placed between a heat generator and a heat dissipator. After reflowing, the thermal resistance and the thickness retention of the carbon nanotube sheet 300 were measured under different loads.

As illustrated in FIG. 9, with an increase in the load applied to the carbon nanotube sheet 300, the thermal resistance decreases monotonously, but the thickness retention does not change significantly.

The formation of the aluminum oxide covering layer 406 on each of the carbon nanotubes 302 can increase the mechanical strength of the carbon nanotubes 302 themselves and the mechanical strength of the bundle structure 308 of the carbon nanotubes 302. This can improve the load tolerance of the carbon nanotube sheet 300 and simultaneously reduce the thermal resistance of the carbon nanotube sheet 300.

In addition, even under an increased load, the thermal resistance can be reduced while the thickness retention does not change significantly. Thus, the margin for the load applied to the carbon nanotube sheet 300 can be increased.

### 3. Third Embodiment

In the third embodiment, zinc oxide (ZnO) is used as the material of the covering layer 306 of the carbon nanotube sheet 300 illustrated in FIG. 3A and FIG. 3B.

In the carbon nanotube sheet 300 according to the third embodiment, in the process illustrated in FIG. 6A, a covering layer 506 made of zinc oxide is formed by ALD over the entire surface of the substrate 502 on which the bundle structure 308 of the carbon nanotubes 302 is formed. The film-forming conditions include the use of diethyl zinc (Zn(C₂H₅)₂) and water (H₂O) as raw material gases and the film-forming temperature of 200° C.

This method is a type of thermal ALD. Plasma enhanced ALD (PEALD) using plasma may also be used.

The zinc oxide covering layer 506 has a thickness of 20 nm.

Under these film-forming conditions, each of the carbon nanotubes 302 can be covered with the zinc oxide covering layer 506 in the longitudinal direction of the carbon nanotubes 302. Under the film-forming conditions, the zinc oxide covering layer 506 continuously covers the entire surface of each of the carbon nanotubes 302 from one end to the other end.

The zinc oxide covering layer 506 covering each of the carbon nanotubes 302 can increase the mechanical strength of the corresponding carbon nanotube 302. This can increase the mechanical strength of the bundle structure 308 of the carbon nanotubes 302 and consequently improve the load tolerance of the carbon nanotube sheet 300.

In the case that the carbon nanotube sheet 300 is used as a thermal interface material between a heat generator (for example, a semiconductor element) and a heat dissipator (for example, a heat spreader), therefore, even the application of an excessive load in a reflow process rarely flattens the bundle structure 308 of the carbon nanotubes 302 in the carbon nanotube sheet 300.

The carbon nanotubes 302 in the bundle structure 308 can be bent to follow the asperities on the surfaces of the heat generator and the heat dissipator. Thus, many of the carbon nanotubes 302 are coupled to the heat generator and the heat dissipator without the filling layer 304 being therebetween, and the number of such carbon nanotubes can be increased. This can thicken the heat conduction path composed of the carbon nanotubes 302 between the heat generator and the heat dissipator. Thus, the carbon nanotube sheet 300 can reduce thermal resistance between the heat generator and the heat dissipator.

When the carbon nanotube sheet 300 that includes the carbon nanotubes 302 each having an end covered with the zinc oxide covering layer 506 is used as a thermal interface material between a heat generator and a heat dissipator, the zinc oxide covering layer 506 on the end of each of the carbon nanotubes 302 is disposed between the heat generator or the heat dissipator and the corresponding carbon nanotube 302.

Zinc oxide has a thermal conductivity of approximately 54 W/m·K. Thus, the thermal conductivity of aluminum oxide is higher than the thermal conductivity per unit area of the bundle structure 308 of the carbon nanotubes 302 (approximately 47.1 W/m·K).

Thus, as described above, the heat conduction path composed of the carbon nanotubes 302 between the heat generator and the heat dissipator can be thicken in the carbon nanotube sheet 300 to reduce thermal resistance between the heat generator and the heat dissipator. Furthermore, the zinc oxide covering layer 506 of each of the carbon nanotubes 302 can form an additional heat conduction path between the heat generator and the heat dissipator. This can further reduce thermal resistance between the heat generator and the heat dissipator.

### 4. Fourth Embodiment

In the fourth embodiment, copper (Cu) is used as the material of the covering layer 306 of the carbon nanotube sheet 300 illustrated in FIG. 3A and FIG. 3B.

In the carbon nanotube sheet 300 according to the fourth embodiment, in the process illustrated in FIG. 6A, a covering layer 606 made of copper is formed by ALD over the entire surface of the substrate 502 on which the bundle structure 308 of the carbon nanotubes 302 is formed. The film-forming conditions include the use of bis(N,N′-diisopropylacetamidinato) copper(I) and hydrogen (H2) as raw material gases and the film-forming temperature of 190° C.

This method is a type of thermal ALD. Plasma enhanced ALD (PEALD) using plasma may also be used.

The copper covering layer has a thickness of 100 nm or less. This is because an excessively large thickness of the copper covering layer 606 results in deterioration of the inherent flexibility of the carbon nanotubes 302.

Under these film-forming conditions, each of the carbon nanotubes 302 can be covered with the copper covering layer 606 in the longitudinal direction of the carbon nanotubes 302. Under the film-forming conditions, the copper covering layer 606 continuously covers the entire surface of each of the carbon nanotubes 302 from one end to the other end.

The copper covering layer 606 covering each of the carbon nanotubes 302 can increase the mechanical strength of the corresponding carbon nanotube 302. This can increase the mechanical strength of the bundle structure 308 of the carbon nanotubes 302 and consequently improve the load tolerance of the carbon nanotube sheet 300.

In the case that the carbon nanotube sheet 300 is used as a thermal interface material between a heat generator (for example, a semiconductor element) and a heat dissipator (for example, a heat spreader), therefore, even the application of an excessive load in a reflow process rarely flattens the bundle structure 308 of the carbon nanotubes 302 in the carbon nanotube sheet 300.

The carbon nanotubes 302 in the bundle structure 308 can be bent to follow the asperities on the surfaces of the heat generator and the heat dissipator. Thus, many of the carbon nanotubes 302 are coupled to the heat generator and the heat dissipator without the filling layer 304 being therebetween, and the number of such carbon nanotubes can be increased. This can thicken the heat conduction path composed of the carbon nanotubes 302 between the heat generator and the heat dissipator. Thus, the carbon nanotube sheet 300 can reduce thermal resistance between the heat generator and the heat dissipator.

When the carbon nanotube sheet 300 that includes the carbon nanotubes 302 each having an end covered with the copper covering layer 606 is used as a thermal interface material between a heat generator and a heat dissipator, the copper covering layer 606 on the end of each of the carbon nanotubes 302 is disposed between the heat generator or the heat dissipator and the corresponding carbon nanotube 302.

Copper has a thermal conductivity of approximately 390 W/m·K. Thus, the thermal conductivity of copper is much higher than the thermal conductivity per unit area of the bundle structure 308 of the carbon nanotubes 302 (approximately 47.1 W/m·K).

Thus, as described above, the heat conduction path composed of the carbon nanotubes 302 between the heat generator and the heat dissipator can be thicken in the carbon nanotube sheet 300 to reduce thermal resistance between the heat generator and the heat dissipator. In addition, the copper covering layer 606 of each of the carbon nanotubes 302 can form an additional heat conduction path between the heat generator and the heat dissipator. This can further reduce thermal resistance between the heat generator and the heat dissipator.

### 5. Fifth Embodiment

5-1. Structure of Electronic Device 1000

FIG. 10 is a schematic cross-sectional view of the structure of an electronic device 1000 according to a fifth embodiment.

A semiconductor element (heat generator) 1004, such as CPU, is disposed on a circuit board 1002, such as a multilayer circuit board. The semiconductor element 1004 is electrically connected to the circuit board 1002 via projection electrodes 1003, such as solder bumps.

The semiconductor element 1004 is covered with a heat spreader (heat dissipator) 1006, which dissipates heat generated by the semiconductor element 1004. A carbon nanotube sheet 1008 according to any one of the first to fourth embodiments is disposed between the semiconductor element 1004 and the heat spreader 1006. The heat spreader 1006 is coupled to the circuit board 1002, for example, with an organic sealant 1010.

In the electronic device 1000 according to the fifth embodiment, the carbon nanotube sheet 1008 according to any one of the first to fourth embodiments is disposed between the semiconductor element 1004 and the heat spreader 1006, that is, between the heat generator and the heat dissipator. The carbon nanotube sheet 1008 is a heat-conductive sheet that functions as a thermal interface material between the semiconductor element 1004 and the heat spreader 1006.

As described above, the carbon nanotube sheet 1008 according to any one of the first to fourth embodiments has very high thermal conductivity in the direction normal to the surface thereof because carbon nanotubes 1012 are oriented in the thickness direction of the sheet. A covering layer 1016 covering each of the carbon nanotubes 1012 can increase the mechanical strength of the corresponding carbon nanotube 1012. This can increase the mechanical strength of a bundle structure 1018 of the carbon nanotubes 1012 and consequently improve the load tolerance of the carbon nanotube sheet 1008.

Thus, in the electronic device 1000, in a reflow process in the manufacturing process described below, even the application of an excessive load to the heat spreader 1006 rarely flattens the bundle structure 1018 of the carbon nanotubes 1012 in the carbon nanotube sheet 1008.

This allows the carbon nanotubes 1012 in the bundle structure 1018 to be bent to follow the asperities on the surfaces of the semiconductor element 1004 and the heat spreader 1006. In the electronic device 1000, therefore, many of the carbon nanotubes 1012 are coupled to the semiconductor element 1004 and the heat spreader 1006 without a filling layer 1014 being therebetween, and the number of such carbon nanotubes can be increased. This can thicken the heat conduction path composed of the carbon nanotubes 1012 between the semiconductor element 1004 and the heat spreader 1006. The carbon nanotube sheet 1008 can reduce thermal resistance between the semiconductor element 1004 and the heat spreader 1006.

In addition, in the electronic device 1000, the load tolerance of the carbon nanotube sheet 1008 can be improved. This can increase the margin for the load applied to the carbon nanotube sheet 1008 in the reflow process. This can facilitate load control in the reflow process.

5-2. Method for Manufacturing Electronic Device 1000

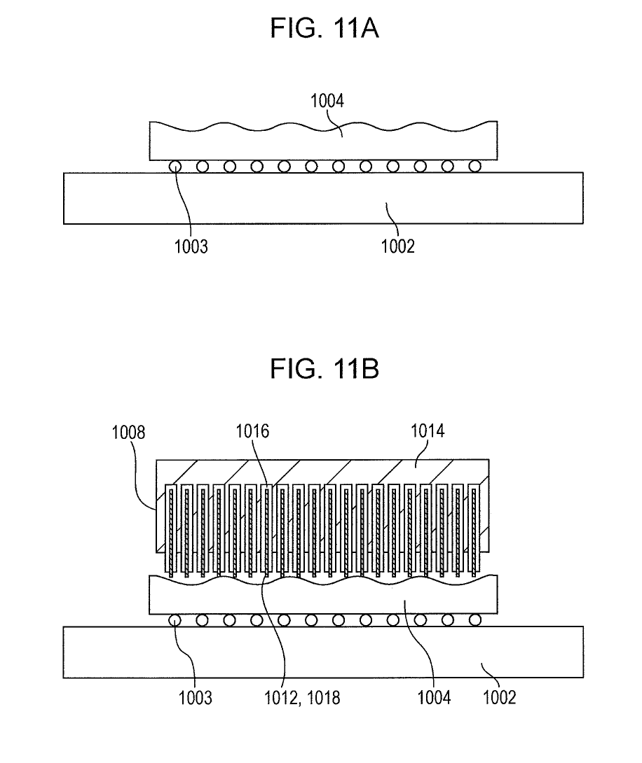

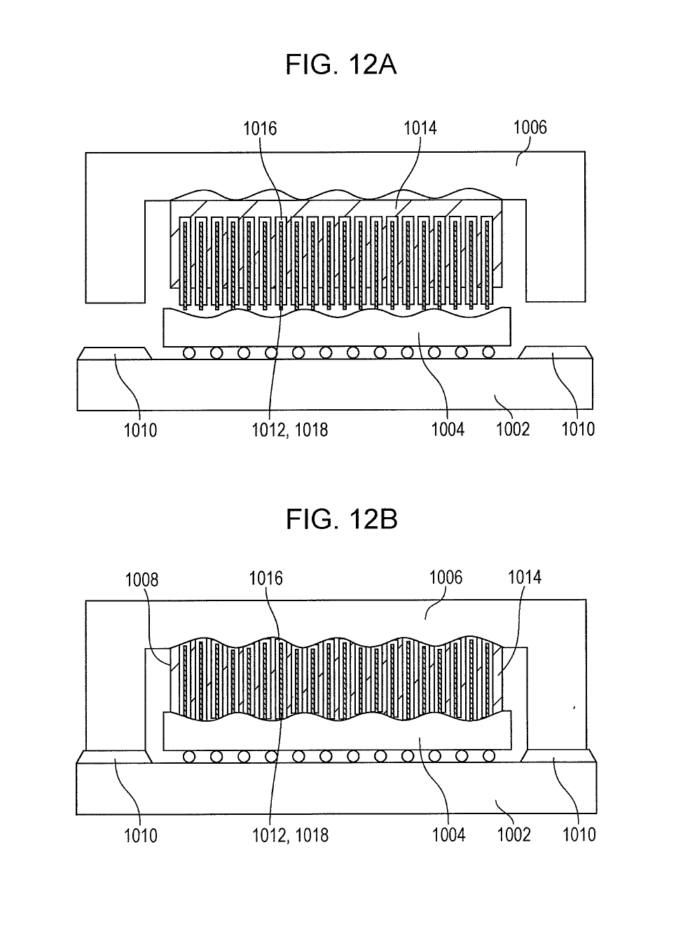

FIGS. 11A, 11B, 12A and 12B are cross-sectional process drawings illustrating a method for manufacturing the electronic device 1000 according to the fifth embodiment.

As illustrated in FIG. 11A, the semiconductor element 1004 is mounted on the circuit board 1002 with the projection electrodes 1003 interposed therebetween. In these drawings, in order to clarify the operation and effect of the carbon nanotube sheet and the electronic device according to the embodiments, asperities on the opposing surfaces of the semiconductor element 1004 and the heat spreader 1006 are exaggerated.

As illustrated in FIG. 11B, the carbon nanotube sheet 1008 according to any one of the first to fourth embodiments is placed on the semiconductor element 1004, which is mounted on the circuit board 1002. The carbon nanotube sheet 1008 is a heat-conductive sheet that can be used as a thermal interface material. Although the example illustrated in FIG. 11B includes the carbon nanotube sheet according to the first embodiment illustrated in FIG. 3A, another carbon nanotube sheet according to any one of the other embodiments may be used.

As illustrated in FIG. 12A, the organic sealant 1010 for fixing the heat spreader 1006 is applied to the circuit board 1002. The heat spreader 1006 is then placed on top of the semiconductor element 1004, on which the carbon nanotube sheet 1008 has been disposed.

The heat spreader 1006 is then heat-treated under a predetermined load to reflow the carbon nanotube sheet 1008. The filling layer 1014 of the carbon nanotube sheet 1008 may be formed of a thermoplastic resin “Micromelt 6239” manufactured by Henkel Japan Ltd. The heat treatment of the carbon nanotube sheet 1008 is performed, for example, at a load of 0.25 MPa at 195° C. for 10 minutes.

The thermoplastic resin of the filling layer 1014 of the carbon nanotube sheet 1008 melts in the heat treatment and follows the asperities on the surfaces of the semiconductor element 1004 and the heat spreader 1006. Thus, the carbon nanotube sheet 1008 changes its shape. This relaxes the binding of the carbon nanotubes 1012 in the carbon nanotube sheet 1008 forced by the filling layer 1014. Thus, the ends of the carbon nanotubes 1012 are coupled to the semiconductor element 1004 and the heat spreader 1006 without the filling layer 1014 being therebetween.

Each of the carbon nanotubes 1012 is covered with the covering layer 1016. The material of the covering layer 306 may be, but is not limited to, a metal oxide, such as aluminum oxide (Al₂O₃) or zinc oxide (ZnO), or a metal, such as copper (Cu), ruthenium (Ru), or platinum (Pt).

The covering layer 1016 can increase the mechanical strength of the carbon nanotubes 1012. This can increase the mechanical strength of the bundle structure 1018 of the carbon nanotubes 1012 and consequently improve the load tolerance of the carbon nanotube sheet 1008. Thus, in the reflow process, even the application of an excessive load to the heat spreader 1006 rarely flattens the bundle structure 1018 of the carbon nanotubes 1012 in the carbon nanotube sheet 1008.

Thus, in the reflow process, even when an excessive load is applied to the heat spreader 1006, the carbon nanotubes 1012 in the bundle structure 1018 can be bent to follow the asperities on the surfaces of the semiconductor element 1004 and the heat spreader 1006. This can increase the number of carbon nanotubes coupled to the semiconductor element 1004 and the heat spreader 1006 without the filling layer 1014 being therebetween and thicken the heat conduction path composed of the carbon nanotubes 1012 between the semiconductor element 1004 and the heat spreader 1006. Thus, the carbon nanotube sheet 1008 can reduce thermal resistance between the semiconductor element 1004 and the heat spreader 1006.

The load in the reflow process may be in such a range that the carbon nanotubes 1012 each covered with the covering layer 1016 can be bent to follow the asperities of the surfaces of the semiconductor element 1004 and the heat spreader 1006, thus achieving sufficient contact with the semiconductor element 1004 and the heat spreader 1006.

The temperature and time of the heat treatment may be in such a range that the thermoplastic resin between the semiconductor element 1004 and the heat spreader 1006 melts and flows, so that the ends of each of the carbon nanotubes 1012 can be coupled to the semiconductor element 1004 and the heat spreader 1006 without the filling layer 1014 being therebetween.

As illustrated in FIG. 12B, the thermoplastic resin of the filling layer 1014 is cooled to room temperature to be solidified, and the heat spreader 1006 is fixed to the circuit board 1002 with the organic sealant 1010. Because of the adhesion properties of the thermoplastic resin, the semiconductor element 1004 and the heat spreader 1006 can be fixed to the carbon nanotube sheet 1008. Thus, after cooled to room temperature, the carbon nanotube sheet 1008 can maintain low thermal resistance between the semiconductor element 1004 and the heat spreader 1006. Thus, the carbon nanotube sheet 1008 functions as a thermal interface material between the semiconductor element 1004 and the heat spreader 1006.

As described above, in the electronic device 1000, the covering layer 1016 covering the carbon nanotubes 1012 can increase the mechanical strength of the bundle structure 1018 of the carbon nanotubes 1012. This can improve the load tolerance of the carbon nanotube sheet 1008.

Thus, in the electronic device 1000, in a reflow process in the manufacturing process described below, even the application of an excessive load to the heat spreader 1006 rarely flattens the bundle structure 1018 of the carbon nanotubes 1012 in the carbon nanotube sheet 1008.

Thus, the carbon nanotubes 1012 in the bundle structure 1018 can be bent to follow the asperities on the surfaces of the semiconductor element 1004 and the heat spreader 1006. This can thicken the heat conduction path composed of the carbon nanotubes 1012 between the semiconductor element 1004 and the heat spreader 1006 in the electronic device 1000. Thus, the carbon nanotube sheet 1008 can reduce thermal resistance between the semiconductor element 1004 and the heat spreader 1006.

In addition, in the electronic device 1000, the load tolerance of the carbon nanotube sheet 1008 can be improved. This can increase the margin for the load applied to the carbon nanotube sheet 1008 in the reflow process. This can facilitate load control in the reflow process.

The embodiments are not limited to the embodiments described above, and various modifications may be made therein.

Although the carbon nanotube sheet has been described as an example of a sheet-shaped structure that includes a line-shaped structure of carbon atoms in these examples, a sheet-shaped structure that includes a line-shaped structure of carbon atoms is not limited to the carbon nanotube sheet. The line-shaped structure of carbon atoms other than carbon nanotube may be carbon nanowire, carbon rod, or carbon fiber. These line-shaped structures have the same characteristics as carbon nanotube except for their sizes. The embodiments can be applied to sheet-shaped structures that include these line-shaped structures.

The constituent materials and the manufacturing conditions are not particularly limited to those described in the embodiments and may be modified for the intended purpose.

The intended use of the carbon nanotube sheet is also not limited to those described in the embodiments. As heat-conductive sheets, the carbon nanotube sheets described in the embodiments can be applied to heat dissipation sheets for CPUs, high power amplifiers for radio communication base stations, high power amplifiers for radio communication terminals, high power switches for electric vehicles, servers, and personal computers. Through the use of excellent allowable current density characteristics of carbon nanotube, the carbon nanotube sheets can be applied to vertical type wiring sheets and various applications using the vertical type wiring sheets.

A carbon nanotube sheet, a sheet-shaped structure, an electronic device, and methods for manufacturing them according to the embodiments have been described. The embodiments are not limited to the examples specifically disclosed above, and various modifications and alterations can be made therein without departing from the claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

1. A sheet-shaped structure, comprising:
a bundle structure that includes a plurality of line-shaped structures of carbon atoms;
a covering layer that covers the line-shaped structures in longitudinal directions of the line-shaped structures, respectively; and
a filling layer that is disposed between the line-shaped structures covered with the covering layer.

2. The sheet-shaped structure of claim 1,
wherein a thermal conductivity of the covering layer is higher than a thermal conductivity per unit area of the bundle structure.

3. The sheet-shaped structure of claim 1,
wherein a thickness of the covering layer is 100 nm or less.

4. The sheet-shaped structure of claim 1,
wherein a surface density of the line-shaped structures of carbon atoms included in the bundle structure is 1×10¹⁰/cm² or more.

5. The sheet-shaped structure of claim 1,
wherein at least part of the plurality of line-shaped structures of carbon atoms are entangled with each other.

6. The sheet-shaped structure of claim 1,
wherein the covering layer covers surfaces of the plurality of line-shaped structures, the surfaces extending from one ends to the other ends of the plurality of line-shaped structures, respectively.

7. The sheet-shaped structure of claim 1,
wherein the filling layer includes a thermoplastic resin.

8. The sheet-shaped structure of claim 7,
wherein a thermal conductivity of the covering layer is higher than a thermal conductivity of the thermoplastic resin.

9. A method for manufacturing a sheet-shaped structure, comprising:
forming a catalyst metal film on a substrate;
forming a plurality of line-shaped structures of carbon atoms above the substrate by using the catalyst metal film as a catalyst;
forming a covering layer by atomic layer deposition, the covering layer covering the line-shaped structures in longitudinal directions of the line-shaped structures, respectively;
forming a filling layer between the line-shaped structures covered with the covering layer; and
removing the plurality of line-shaped structures of carbon atoms from the substrate and the catalyst metal film.

10. An electronic device, comprising:
a heat generator;
a heat dissipator; and
a thermal interface material disposed between the heat generator and the heat dissipator, the thermal interface material including a bundle structure that includes a plurality of line-shaped structures of carbon atoms, a covering layer that covers the line-shaped structures in longitudinal directions of the line-shaped structures, respectively, and a filling layer that is disposed between the line-shaped structures covered with the covering layer.

11. The electronic device of claim 10,
wherein both ends of the plurality of line-shaped structures of carbon atoms included in the thermal interface material are coupled to the heat generator and the heat dissipator without the filling layer being interposed therebetween.

12. A method for manufacturing an electronic device, comprising:
placing a thermal interface material between a heat generator and a heat dissipator, the thermal interface material including a bundle structure that includes a plurality of line-shaped structures of carbon atoms, a covering layer that covers the line-shaped structures in longitudinal directions of the line-shaped structures, and a filling layer that is disposed between the line-shaped structures covered with the covering layer;
melting the filling layer by heating the thermal interface material while a load is applied between the heat generator and the heat dissipator; and
solidifying the filling layer by cooling the thermal interface material.
